(19) United States
(12) Patent Application Publication
(10) Pub. No.: US 2006/0126408 A1
(43) Pub. Date: Jun. 15, 2006

(54) Memory buffer

(75) Inventor: Thorsten Bucksch, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/283,072

(22) Filed: Nov. 21, 2005

(30) Foreign Application Priority Data
Nov. 22, 2004 (DE) 10 2004 056 214.8

(51) Int. Cl. G11C 29/00

(52) U.S. Cl. 365/200

(57) ABSTRACT

The invention relates to a memory buffer, a method for operating the memory buffer, a memory module with a memory buffer, a testing method for the memory module, and an operating method for the memory module. The memory buffer comprises at least one memory logic unit that is connected with at least one memory-side bus system and with at least one host-side bus system, and that is characterized in that at least one redundancy memory is further available, so that a comparison of at least one memory cell address of said memory logic unit with at least one further memory cell address can be performed, and a transmission of at least one bus signal can be switched between said memory-side bus system and said redundancy memory on the basis of the comparison.

### CLAIM FOR PRIORITY

This application claims the benefit of prior German Application No. 10 2004 056 214.8, filed in the German language on Nov. 22, 2004, the contents of which are hereby incorporated by reference.

### TECHNICAL FIELD OF THE INVENTION

The invention relates to a memory buffer, a method for operating the memory buffer, a memory module comprising a memory buffer, a testing method for the memory module, and an operating method for the memory module.

### BACKGROUND OF THE INVENTION

Semiconductor devices, e.g. corresponding, integrated (analogue or digital) 15 computing circuits, semiconductor memory devices such as functional memory devices (PLAs, PALs, etc.) and table memory devices (e.g. ROMs or RAMs, in particular SRAMs and DRAMs), etc. are subject to comprehensive tests in the course of their manufacturing process.

For the common manufacturing of a plurality of (in general identical) semiconductor devices, a so-called wafer (i.e. a thin disc consisting of monocrystalline silicon) is used. The wafer is treated appropriately (e.g. subject successively to a plurality of coating, exposure, etching, diffusion and implantation process steps, etc) and subsequently e.g. sawn apart (or e.g. scratched, and broken), so that the individual devices are then available.

During the manufacturing of semiconductor devices (e.g. of DRAMS (Dynamic Random Access Memories), in particular of DDR-DRAMs (Double Data Rate DRAMs)—even before all the desired, above-mentioned processing steps have been performed with the wafer—(i.e. already in a semi-finished state of the semiconductor devices), the (semi-finished) devices (that are still on the wafer) may be subject to appropriate testing methods (e.g. kerf measurements at the wafer scratch frame) at one or a plurality of testing stations by means of one or a plurality of testing devices.

After the finishing of the semiconductor devices (i.e. after the performing of all the above-mentioned wafer processing steps), the semiconductor devices are subject to further testing methods. For instance, by means of appropriate (further) testing devices, the devices—that are finished, but still positioned on the wafer—may be tested appropriately (“disc tests”).

Correspondingly, tests may be performed (at appropriate further testing stations, and by using appropriate, further testing devices) e.g. after the incorporation of the semiconductor devices in the corresponding semiconductor device housings, and/or e.g. after the incorporation of the semiconductor device housings (together with the respective semiconductor devices incorporated therein) in appropriate electronic modules (so-called “module tests”).

When testing semiconductor devices, so-called “DC tests” and/or so-called “AC tests” may, for instance, be employed as testing methods (e.g. with the above-mentioned disc tests, module tests, etc.).

In a DC test, for instance, a voltage (or current) of predetermined—in particular constant—intensity may be applied to a corresponding pin of a semiconductor device to be tested. Then, the intensity of—resulting—currents (or voltages) may be measured, in particular it may be examined whether these currents (or voltages) are within predetermined, desired thresholds.

In contrast, in an AC test, for instance, voltages (or currents) of alternating intensity may be applied to corresponding pins of a semiconductor device, in particular appropriate test pattern signals, by means of which appropriate functioning tests can be performed at the respective semiconductor device.

By means of the above-mentioned testing methods, defective semiconductor devices or modules, respectively, i.e. those having defective memory cells, can be identified and then be sorted out (or partially also be repaired), and/or the process parameters used for the manufacturing of the devices may—corresponding to the test results achieved—be modified appropriately or be adjusted optimally, etc., etc.

In a plurality of applications—e.g. in server or work station computers, etc.—memory modules with upstream memory buffers can be used, e.g. so-called “buffered DIMMs”.

Such memory modules in general comprise one or a plurality of semiconductor devices, in particular DRAMS (e.g. DDR-DRAMs), and one or a plurality of memory buffers (e.g. corresponding DDR-DRAM memory buffers standardized by JEDEC) upstream the semiconductor memory devices.

The memory buffers may, for instance, be arranged on the same circuit board as the DRAMs.

The memory modules are—in particular by interposing an appropriate memory controller (which is, for instance, positioned externally of the respective memory module)—connected with one or a plurality of microprocessors of the respective server or work station computer, etc.

In the case of “partially” buffered memory modules, the address and command signals—that are e.g. output by the memory controller or by the respective processor—can be buffered (shortly) by appropriate memory buffers, and correspondingly similar address and command signals can be transmitted to the memory devices, e.g. DRAMs, in a time-coordinated, possibly multiplexed or demultiplexed manner.

In contrast to this, the (reference) data signals output by the memory controller or by the respective processor, respectively, may be transmitted directly, i.e. without buffering by an appropriate memory buffer, to the semiconductor devices (and—vice versa—the (reference) data signals output by the semiconductor devices may be transmitted directly—without interposition of an appropriate memory buffer—to the memory controller or the respective processor).

Contrary to this, in the case of fully buffered memory modules, both the address and command signals exchanged between the memory controller or the respective processor and the semiconductor devices, and the corresponding (reference) data signals are buffered by appropriate memory buffers and are transmitted to the semiconductor devices or the memory controller, respectively, or to the respective processor thereafter only.

For storing the data generated during the above-mentioned testing methods (or during any other testing methods), in particular corresponding test (result) data, appropriate, specific test data registers may be provided on the respectively tested semiconductor devices (e.g. the above-mentioned analogue or digital computing circuits, the above-mentioned semiconductor memory devices (PLAs, PALs, ROMs, RAMs, in particular SRAMs and DRAMs, e.g. DDR-DRAMs, etc.)

However, despite the testing of the semiconductor devices (DRAMs etc.) or of the modules, respectively, malfunctions that have not yet been detected may occur, e.g. by insufficient testing of the components, by errors, or by loss of quality during assembly, or by ageing, etc. In the worst case, this may result in the breakdown of a computer system.

But also in the production process it is, for reasons of quality, disadvantageous to exchange semiconductor devices that have been detected as defective. Often, the entire memory module is rejected then.

### SUMMARY OF THE INVENTION

The invention provides a simple and flexible possibility of correcting malfunctions of a semiconductor device or of a corresponding memory cell, respectively, even after an assembly.

In accordance with one embodiment of the invention, there is a memory buffer comprising at least one memory logic unit that is connected with at least one memory-side bus system and with at least one host-side bus system.

Host-side means that bus signals between a host utilizing the memory buffer—e.g. a memory controller or a respective processor—and the memory buffer can be exchanged via this bus system. In the case of “partially” buffered memory modules, these are typically address and command signals, in the case of “fully” buffered memory modules also the data signals. Memory-side correspondingly means that bus signals between the memory buffer and at least one semiconductor device (e.g. a DRAM) can be exchanged via this bus system.

By means of the memory logic unit, the bus signals can be buffered (shortly) and can be transmitted to the semiconductor devices, e.g. DRAMs, in a time-coordinated, possibly multiplexed or demultiplexed manner, via the memory-side bus system.

The memory buffer is further equipped such that at least one redundancy memory is available. The memory cells available in the redundancy memory replace in operation memory cells that have been detected as defective on the semiconductor devices. Therefore, semiconductor devices that have been detected as defective need no longer be exchanged, but the number of defective memory cells should, of course, not exceed the size of the redundancy memory. In particular in this case, additional other correction mechanisms may be applicable.

By a comparison of at least one—physical or logic—memory cell address stored in the memory logic unit or sent thereto with at least one further memory cell address, a transmission of at least one bus signal can be switched between the memory-side bus system and the redundancy memory. Typically, but not restricted thereto, this may happen such that a host-side bus signal is received in the memory buffer, in particular to the memory logic unit. The (one- or multi-cycle) bus signal also comprises an address signal that contains a memory cell address, usually of a memory cell of a semiconductor device. This memory cell address is then compared with (at least) one further memory cell address, advantageously the defective memory cell address itself. In this advantageous case, memory cell addresses that are available in address signals—and that usually arrive at the host side—are compared with a “list” of defective memory cells.

Information about memory cell addresses may, apart from the actual memory cell address, also comprise further indications such as a “fail” flag and/or the memory cell address of the memory cell of the redundancy memory that is to replace the memory cell of the semiconductor memory device, or the like.

The memory buffer is designed such that it is adapted to switch, on the basis of the comparison, a transmission of at least one bus signal between the memory-side bus system and the redundancy memory.

It is thus adapted to switch or deflect the memory-side bus signal provided via the memory-side bus system, e.g. for controlling an addressed memory cell of a semiconductor memory, to the redundancy memory or to a memory cell of the redundancy memory, respectively. Therefore, a memory cell of the redundancy memory can be utilized instead of the defective memory cell of the semiconductor memory device.

This makes it easy for a host to control the memory module on which the memory buffer is positioned. It is also possible, e.g. by means of new tests, to newly configure the memory buffer. Thus—even in the assembled state—a plurality of memory or module tests can be performed, the result of which (namely defective memory cell addresses) yields a new “list” of further memory cell addresses, possibly linked with corresponding addresses of redundancy memory cells.

The memory buffer advantageously comprises at least one additional address register for storing at least one of the further memory cell addresses.

It preferable if the additional address register can be configured via a configuration bus, in particular can be filled with memory cell addresses (or with information containing same). The configuration bus may, for instance, lead to a non-volatile memory, in particular a PROM, e.g. an EEPROM, available on the memory module. The non-volatile memory may, for instance, comprise the test information of the new memory test, e.g. a (possibly updated) list of defective memory cell addresses and—if required—corresponding addresses of redundancy memory cells linked therewith.

It is preferable if the memory buffer comprises a redundancy address decoder for performing the comparison of the memory cell addresses, i.e. between a memory cell address stored in the memory logic unit or sent thereto and at least one further memory cell address.

It is also preferable if the memory logic unit is connected with the redundancy memory via a redundancy bus system, so that, on the basis of the comparison of the memory cell addresses, a transmission of at least one bus signal can be switched between the memory-side bus system and the redundancy bus system.

It is advantageous if the bus signal can be switched between the memory-side bus system and the redundancy bus system by means of a change-over switch, in particular a multiplexer. It is preferable if the change-over switch is connected with the redundancy address decoder via a data connection, so that the redundancy address decoder can promptly transmit a signal about a memory cell that has been identified as defective to the change-over switch which can then transmit the bus signal to the redundancy bus system. An address signal received by the memory logic unit and pertaining to a bus signal can, for instance, be extracted and be transmitted to the redundancy address decoder. There, the address is compared with an address stored in the redundancy memory. The address stored in the redundancy memory is part of an information string that moreover comprises a “replacement” redundancy memory address. If detected as defective, a signal comprising e.g. the redundancy memory address and/or the original memory address received by the memory logic unit is transmitted to the change-over switch. By means of the change-over switch, the original address—pertaining to a semiconductor device—may, for instance, be exchanged in the corresponding bus signal for the redundancy memory address, so that the bus signal is now transmitted to the redundancy memory and addresses the corresponding—logic or physical—memory cell there.

It is advantageous if the redundancy memory comprises SRAMs or register cells.

In another embodiment of the invention, there is a method for operating a memory buffer in which memory cell addresses received by or stored in the memory logic unit—in particular the host-side address bus—are compared with the further memory cell addresses that are in particular stored in the additional address register and, depending on the outcome of the comparison, at least one bus signal is either transmitted via the memory-side bus system or to the redundancy memory. If there is no information available in the additional address register, the address comparison may be interrupted, e.g. by setting a “no fail” flag.

This method is advantageous if the further memory cell addresses stored in the redundancy memory correspond to defective memory cells and, on concurrence between memory cell addresses received by the memory logic unit and memory cell addresses stored in the additional address register, a corresponding (reference) bus signal (i.e., for instance, with substantially equal command and data signals, but a replaced address signal) is transmitted to the redundancy memory.

In still another embodiment of the invention, there is a memory module comprising at least one inventive memory buffer and at least one semiconductor device that is typically connected therewith via the memory-side bus system.

In yet another embodiment, there is a memory module that additionally comprises a non-volatile memory, in particular an EEPROM, which is connected with the additional address register e.g. via the configuration bus. Thus, information about defective memory cells or memory cell addresses that is stored in the non-volatile memory may, after the powering up of the host, e.g. a PC or a server, be transmitted from the non-volatile memory to the—usually quicker—additional address register. Storing is, for instance, indeed also possible in a non-volatile memory outside the memory module, but then information would possibly be lost or be interpreted wrongly during the disassembly/exchange of the memory module.

In another embodiment of the invention, there is a method for testing or for initializing a memory, including:

testing memory cells of the at least one semiconductor device (2a,2b,2c) for their functional efficiency, and

storing memory cell addresses of functionally inefficient memory cells, preferably in a non-volatile memory.

These steps may, for example, be preceded by the powering up of the system comprising the memory module. During testing, the storing of the memory cell addresses can, in an interim step, also be performed in a—usually quicker—buffer, e.g. the additional address register, wherein the information is then favorably transmitted to the non-volatile memory. If no defective memory cells are detected, advantageously no information about memory cell addresses is stored. Rather, a “no fail” flag may be set, which enables a temporary switching off of the memory cell replacement in a later operation.

It is advantageous if memory cell addresses of the redundancy memory are assigned to the memory cell addresses of the functionally inefficient memory cells, in particular in a common information packet/information string.

In still another embodiment of the invention, there is a method for operating a memory module in which the above-described testing method has been performed at least once in advance (i.e. for initialisation). By that, information about defective memory cell addresses—if available—has been stored—preferably in a non-volatile memory. In a first step, the memory cell addresses of the functionally inefficient memory cells are read out from the non-volatile memory and are transmitted to the additional address register for quicker processing. In a second step and in further steps, the comparison and switching operations are then performed. If no information about memory cell addresses is stored, the first step or the entire method, respectively, optionally is not performed.

### BRIEF DESCRIPTION OF THE DRAWINGS

In the following, the invention will be explained in more detail with reference to the embodiments and the drawings. In the drawings:

FIG. 1 shows a partially buffered memory module.

FIG. 2 shows a fully buffered memory module.

FIG. 3 shows an exemplary front and back view of a memory module.

FIG. 4 shows an exemplary memory module with a memory buffer.

FIG. 5 shows the course of operation of a testing or initialization method for a memory module.

FIG. 6 shows the operating procedure of a memory module.

### DETAILED DESCRIPTION OF THE INVENTION

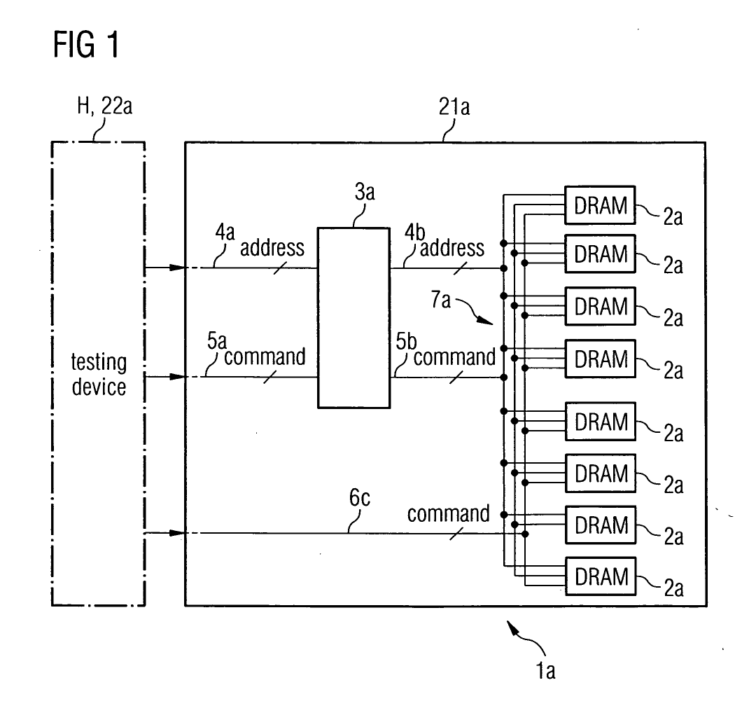

FIG. 1 shows a schematic representation of a partially buffered memory module (e.g. a “buffered DIMM” 1a) in which—by way of example—a testing method can be used.

As results from FIG. 1, the memory module 1a illustrated there comprises a plurality of semiconductor devices 2a and (e.g. one) memory buffer 3a upstream the semiconductor devices 2a.

The semiconductor devices 2a may, for instance, be functional memory devices or table memory devices (e.g. ROMs or RAMs), in particular DRAMs, e.g. DDR-DRAMs or DDR2-DRAMs, etc.

As results from FIG. 1, the semiconductor devices 2a may be arranged on the same circuit board 21a as the memory buffers 3a.

The memory buffers 3a may, for instance, be (“registered DIMM”) DRAM, in particular DDR-DRAM or DDR2-DRAM memory buffers standardized by JEDEC.

The memory module 1a may be connected to a host H (e.g. a testing device 22a for testing the memory module 1a) utilizing the semiconductor devices 2a. A host H may, for instance, be a memory controller (not illustrated) or a microprocessor (not illustrated). Typically, the memory module 1a is—especially by interposition of a memory controller (that is e.g. arranged externally of the memory module 1a, in particular externally of the above-mentioned circuit board 21a)—connected with one or a plurality of microprocessors, in particular one or a plurality of microprocessors of a server or work station computer (or any other microprocessor, e.g. of a PC, a laptop, etc.).

As results from FIG. 1, with the partially buffered memory module 1a illustrated there, the address and command signals output e.g. by the memory controller or by the respective processor are not directly transmitted to the semiconductor devices 2a.

Instead, the address signals are—e.g. via a corresponding host-side address bus 4a (or corresponding address lines) (“address”)—, and the command signals are—e.g. via a corresponding host-side command bus 5a (or corresponding command lines) (“command”) first of all supplied to the memory buffer 3a.

The command signals may be any kind of command signals used with conventional memory modules, e.g. corresponding read and/or write and/or chip select (semiconductor device select) command signals, etc., to the extent that they are supported by the protocol of the memory buffer 3a.

In the memory buffer 3a, the corresponding signals (address signals, command signals) are buffered—shortly—and are transmitted to the semiconductor devices 2a in a time-coordinated, possibly multiplexed or demultiplexed manner (e.g. via an appropriate—central—memory bus 7a (with an appropriate memory-side command bus 5b and an appropriate memory-side address bus 4b with corresponding command and address lines)).

In contrast to that, with the partially buffered memory module 1a illustrated in FIG. 1, the (reference) data signals (“data”) output by the host H—e.g. by the above-mentioned memory controller or by the respective processor—can be transmitted directly, i.e. without buffering by the memory buffer 3a, to the semiconductor devices 2a via a continuous data bus 6c, (e.g. via a data bus 6c that is directly connected with the above-mentioned, central memory bus 15a (or via corresponding data lines, respectively)).

Vice versa, the (reference) data signals output by the semiconductor devices 2a can also be transmitted directly—without interposition of the memory buffer 3a—to the host H, i.e., for instance, the testing device 22a, a memory controller, or the respective processor (e.g. again via the above-mentioned continuous data bus 6c that is directly connected with the central memory bus 7a).

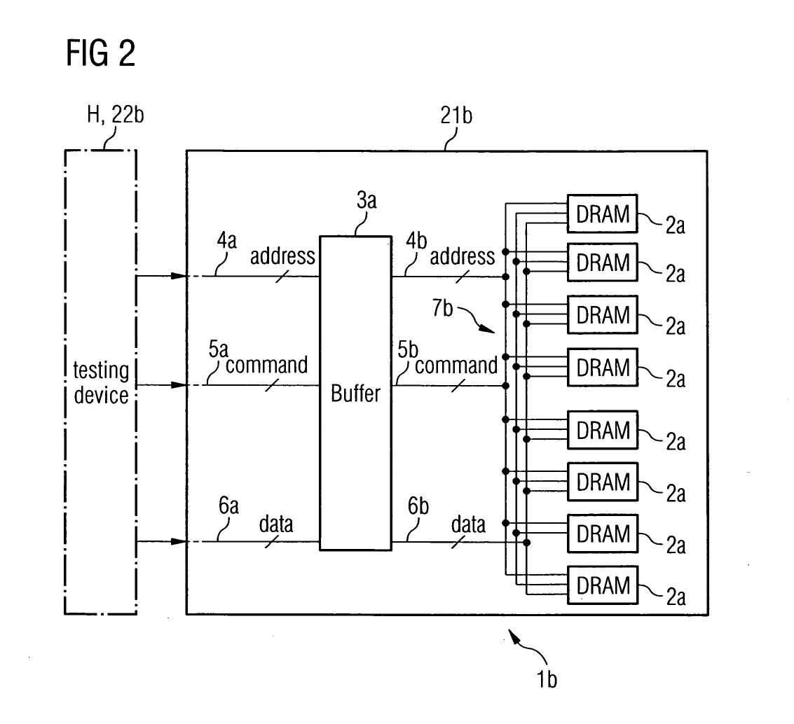

FIG. 2 shows a schematic representation of a fully buffered memory module 1b (here: a “buffered DIMM” 1b).

As results from FIG. 2, the memory module 1b illustrated there comprises—corresponding to the partially buffered memory module 1a according to FIG. 1—a plurality of semiconductor devices 2a and one or a plurality of memory buffers 3b upstream the semiconductor devices 2a.

The semiconductor devices 2a may, for instance, be functional memory or table memory devices (e.g. ROMs or RAMs), in particular DRAMs, e.g. DDR-DRAMs or DDR2-DRAMs, etc.

The semiconductor devices 2a may be arranged on the same circuit board 21b as the memory buffer 3b.

The memory buffer 3b may, for instance, be appropriate, standardized DRAM, in particular DDR-DRAM or DDR2-DRAM data buffer devices (e.g. “fully buffered” data buffer devices standardized by a consortium lead-managed by Intel, together with JEDEC (e.g. FB-DIMM or fully buffered DIMM memory buffers)).

The memory module 1b may (correspondingly similar to the memory module 1a illustrated in FIG. 1)—in particular by interposition of an appropriate (not illustrated) memory controller (that is e.g. arranged externally of the memory module 1b, in particular externally of the above-mentioned circuit board 21b)—be connected with one or a plurality of microprocessors, in particular one or a plurality of microprocessors of a server or work station computer (or any other microprocessor, e.g. of a PC, a laptop, etc.).

As results from FIGS. 1 and 2, the memory module 1b illustrated in FIG. 2 is of a correspondingly similar or identical structure as and operates correspondingly similarly or identically to the memory module 1a illustrated in FIG. 1, except that the (reference) data signals exchanged between the host H and the semiconductor devices 2a are also buffered by a memory buffer 3b.

In the memory buffer 3b, the corresponding data signals emanating from the host (e.g. testing device 21b, memory controller, processor, etc.) and transmitted, for instance, via a host-side data bus 6a can be buffered—shortly—and be transmitted via a memory-side data bus 6b to the semiconductor devices 2a in a time-coordinated, possibly multiplexed or demultiplexed manner (e.g. via a central memory bus 7b (with an appropriate memory-side command, address, and data bus 4b, 5b, 6b with corresponding command, address, and data lines)).

Vice versa, the data signals output by the semiconductor devices 2b e.g. at the above-mentioned central memory bus 7b may also be buffered—shortly—in the buffer 3b and be transmitted to the host in a time-coordinated, possibly multiplexed or demultiplexed manner, e.g. via the above-mentioned host-side data bus 6a.

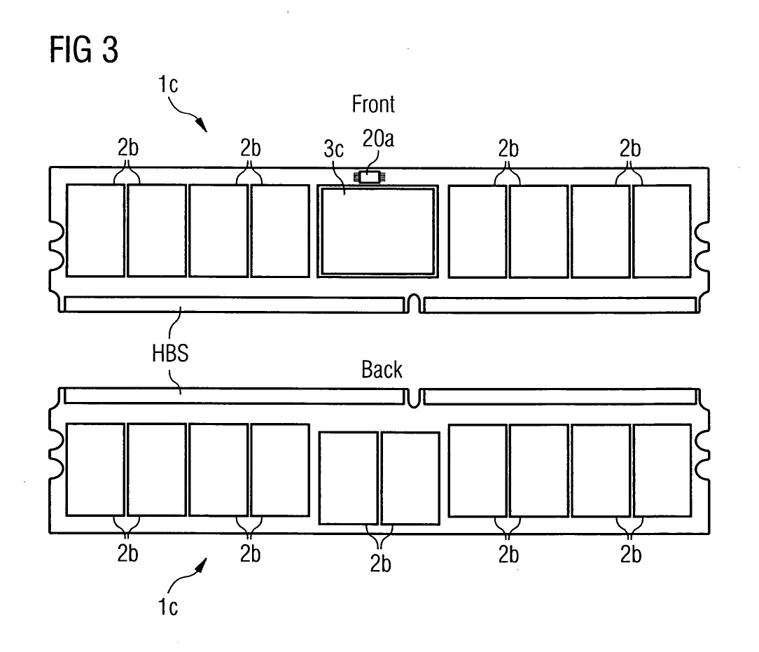

FIG. 3 shows a side view of a front (top) and a back (bottom) of a memory module 1c. While on the back of the circuit board substantially only semiconductor (memory) devices 2b are applied, both a memory buffer 3c and a non-volatile memory 20a in the form of an EEPROM are positioned on the front. The semiconductor devices 2b are preferably DRAMs.

The memory module 1c is connected with a host via signal lines, typically a host-side bus system HBS. The host may be any unit addressing at least one of the semiconductor devices 2b, i.e., for instance, a testing device, a computing device such as a PC, a server, a handheld, etc., or a memory controller, etc.

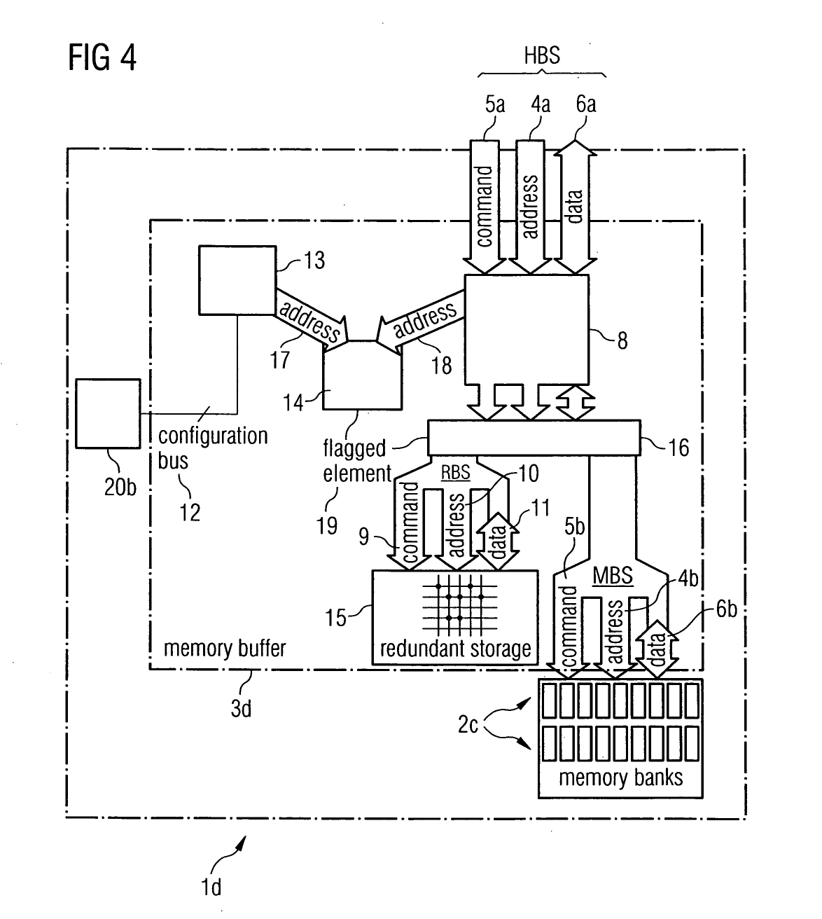

FIG. 4 schematically shows a fully buffered memory module 1d with a memory buffer 3d, with semiconductor devices 2a, and with a non-volatile memory 20b.

Into the memory buffer 3d there leads a host-side bus system HBS comprising a host-side command bus 5a (“command”), a host-side address bus 4a (“address”), and a host-side data bus 6a (“data”). In this embodiment, command signals are transmitted unidirectionally via the host-side command bus 5a and address signals are transmitted unidirectionally via the host-side address bus 4a to the memory module 1d while data signals may be transmitted bidirectionally via the host-side data bus 6a. The host-side bus system HBS leads to a memory logic unit 8. The memory logic unit 8 is connected with semiconductor devices 2c, in particular DRAMs, at the other side, i.e. at the memory side, via a memory-side bus system MBS—comprising a unidirectional memory-side command bus 5b, a unidirectional memory-side address bus 4b, and a bidirectional memory-side data bus 6b. Between the memory logic unit 8 and the memory-side bus system MBS there is positioned a change-over switch in the form of a multiplexer 16 for multiplexing and/or demultiplexing bus signals.

Furthermore, an additional address register 13 and a redundancy address decoder 14 are available. Via respective data connections 17, 18, memory addresses (or information containing same, respectively) from the memory logic unit 8 or those that are transmitted to the memory logic unit 8, respectively, on the one hand, and memory addresses (or information containing same, respectively) from the additional address register 13, on the other hand, are transmitted to the redundancy address decoder 14. There, the addresses are compared. In case there is a concurrence in content, a signal is sent to the multiplexer 16 via the data connection 19, e.g. an information string with an address of the semiconductor device 2c which is to be replaced, a replacement address in a redundancy memory 15—that will be described further below—, and possibly additional information. The time coordination is ideally such that the method steps of ‘sending the memory cell address to the redundancy address decoder 14’—‘comparing the memory cell addresses’—‘sending a signal to the multiplexer 16’ last as long as the guiding of the corresponding bus signal through the memory logic unit 8. Thus, the corresponding bus signal then may, e.g. in the case of a positive comparison on identification of an addressed defective memory cell and emitting of a corresponding information to the multiplexer 16, be switched or deflected, respectively, to a redundancy bus system RBS with a redundancy command bus 9, a redundancy address bus 10, and a bidirectional redundancy data bus 11, connected with the multiplexer 16. This may, for instance, happen by replacing the address of the defective memory cell by the (replacement) address in the redundancy memory 15. The modified bus signal that is to be deflected to the redundancy memory 15 will then comprise the modified address and the command and data signals of identical content.

From the redundancy bus system RBS the bus signal gets to the redundancy memory 15, here: a SRAM, with corresponding memory cells that are addressed by the bus signal in correspondence with the memory cells of the semiconductor devices 2c, e.g. in that data are written in or read out of the memory cells of the redundancy memory 15.

The additional address register 13 is adapted to be configured, e.g. written, via a configuration bus 12 emanating from the memory buffer 3d. In this embodiment, the additional address register 13 is connected with a non-volatile memory 20b of the memory module 1d in the form of an EEPROM. The EEPROM may comprise further (not illustrated) data lines, e.g. outward for connection to a host.

FIG. 5 shows, in the form of a flowchart, an embodiment of a method for testing or initialising, respectively, a memory module 1c, 1d.

To begin with, the system host H memory module is powered up and possibly configured (“system initialisation”). The host H may, for instance, be an independent testing device or a computing device (microprocessor, microcontroller, etc.) with an incorporated testing routine.

Then, the semiconductor devices are tested for their functional efficiency (“memory test”). If no errors are detected (“Pass?: yes”), the memory module is ready for use (possibly by setting a “no fail” flag). No correction/redundancy routines will be called then as a rule.

If, however, defective memory cells are found (“Pass?: no”), their addresses or information containing same, respectively, are stored (“store fail addresses”). In this flowchart this happens in the additional memory register 13b (“buffer register”) of the memory buffer 3d, which is relatively fast and can be written frequently.

After conclusion of the actual testing procedure or the storing of the memory addresses, respectively, the data of the address register 13b are retransmitted to the host H (“host: read fail addresses from mem. Buffer”) and possibly processed. From there, redundancy information—also e.g. the defective memory addresses, possibly with corresponding memory cell addresses of the redundancy memory 15—is stored in a non-volatile memory 20c (“store redundancy information non-volatile”), preferably in an EEPROM available on the memory module.

This testing method can be performed as many times as desired, even in the state of the memory buffer in which it is already incorporated in the host.

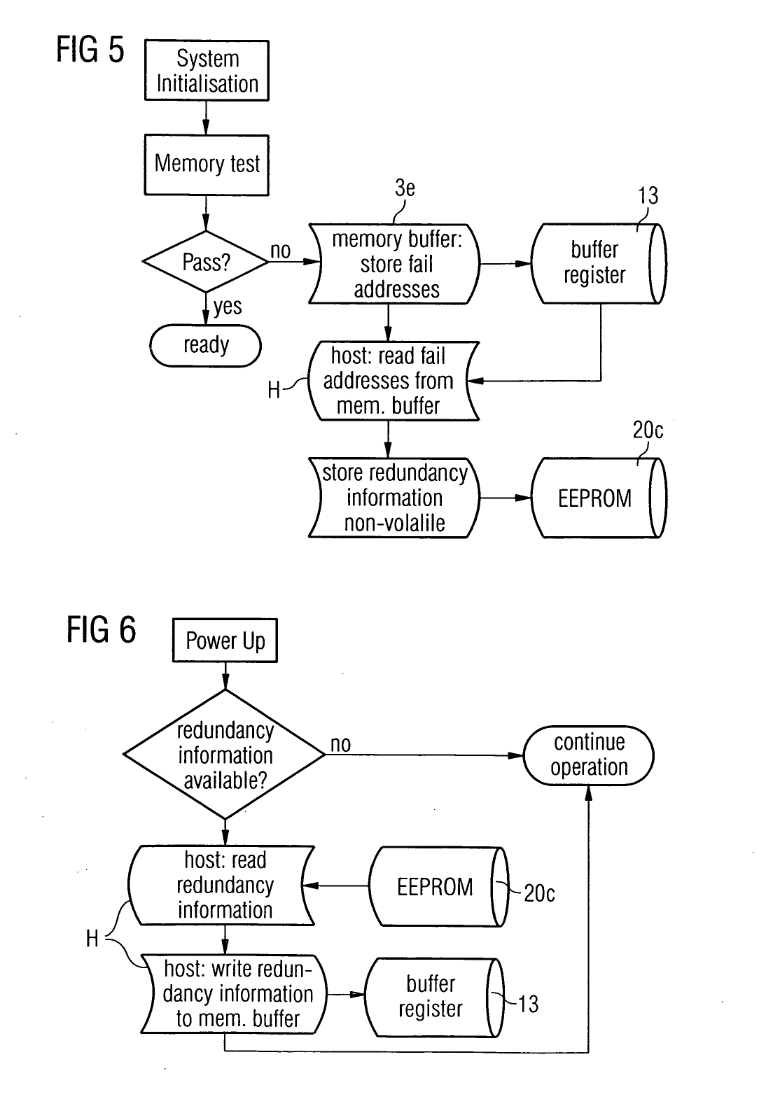

FIG. 6 shows, in the form of a flowchart, a method for operating the inventive memory module.

After powering up (“Power Up”), it is examined whether there is redundancy information available (“redundancy information available?”). If not (“no”), the memory module is directly released for operation. If yes, the redundancy information is read out by the host from the—relatively slow—EEPROM 20c (“host: read redundancy information”) and written into the—relatively fast—additional address register (“buffer register”) (“host: write redundancy information to mem. Buffer”). Next, the operation is started as has been described by way of example also in FIG. 4.

The operating method is advantageously, but not necessarily, preceded by the testing method that has been described by way of example in FIG. 5.

### List of Reference Signs

1a partially buffered memory module
1b fully buffered memory module
1c memory module
1d memory module
2a semiconductor device
2b semiconductor device
2c semiconducor device
3a memory buffer
3b memory buffer
3c memory buffer
3d memory buffer
3e memory buffer
4a host-side address bus
4b memory-side address bus
5a host-side command bus
5b memory-side command bus
6a host-side data bus
6b memory-side data bus
6c continuous data bus
7a memory bus
7b memory bus
8 memory logic unit
9 redundancy command bus
10 redundancy address bus
11 redundancy data bus
12 configuration bus
13 additional address register
13b additional address register
14 redundancy address decoder
15 redundancy memory
16 multiplexer
17 data connection
18 data connection
19 data connection
20a non-volatile memory
20b non-volatile memory
20c non-volatile memory
21a circuit board
21b circuit board
22a testing device
22b testing device
H host
HBS host-side bus system
MBS memory-side bus system
RBS redundancy bus system

What is claimed is:

1. A memory buffer, comprising:
a memory logic unit connected with at least one memory-side bus system and at least one host-side bus system; and
at least one redundancy memory, wherein
a comparison of at least one memory cell address of the memory logic unit with at least one further memory cell address can be performed, and
a transmission of at least one bus signal can be switched between the memory-side bus system and the redundancy memory based on the comparison.

2. The memory buffer according to claim 1, wherein at least one additional address register is available at least for storing the at least one further memory cell address.

3. The memory buffer according to claim 2, wherein the additional address register is adapted to be filled with memory cell addresses, via a configuration bus.

4. The memory buffer according to claim 1, wherein the comparison of the memory cell addresses can be performed by a redundancy address decoder.

5. The memory buffer according to claim 1, wherein the memory logic unit is connected with the redundancy memory via a redundancy bus system (RBS) such that a transmission of at least one bus signal can be switched between the memory-side bus system and the redundancy bus system based on the comparison.

6. The memory buffer according to claim 5, wherein the bus signal between the memory-side bus system and the redundancy bus system can be switched by a change-over switch in a multiplexer.

7. The memory buffer according to claim 6, wherein the change-over switch is connected with the redundancy address decoder via a data connection.

8. The memory buffer according to claim 1, wherein the redundancy memory comprises SRAMs or register cells.

9. A method for operating a memory buffer according to claim 1, wherein
memory cell addresses received in the memory logic unit at the host side are compared with the further memory cell addresses stored in particular in the additional address register, and
depending on the outcome of the comparison, at least one bus signal is either transmitted via the memory-side bus system or to the redundancy memory.

10. The method according to claim 9, wherein
the further memory cell addresses stored in the redundancy memory correspond to defective memory cells, and
on concurrence between memory cell addresses received in the memory logic unit and memory cell addresses stored in the additional address register, a bus signal is transmitted to the redundancy memory.

11. A memory module, comprising:
at least one memory buffer comprising
a memory logic unit connected with at least one memory-side bus system and at least one host-side bus system; and
at least one redundancy memory, wherein
a comparison of at least one memory cell address of the memory logic unit with at least one further memory cell address can be performed, and
a transmission of at least one bus signal can be switched between the memory-side bus system and the redundancy memory based on the comparison; and
at least one semiconductor device connected therewith via the memory-side bus system.

12. The memory module according to claim 11, further comprising a non-volatile memory that is connected with the additional address register via a configuration bus.

13. A method for testing a memory module, the memory module comprising at least one memory buffer comprising a memory logic unit connected with at least one memory-side bus system and at least one host-side bus system; and at least one redundancy memory, wherein a comparison of at least one memory cell address of the memory logic unit with at least one further memory cell address can be performed, and a transmission of at least one bus signal can be switched between the memory-side bus system and the redundancy memory based on the comparison; and at least one semiconductor device connected therewith via the memory-side bus system, wherein
the memory cells of the at least one semiconductor device are tested for their functional efficiency, and
information concerning the memory cell addresses of the functionally inefficient memory cells is stored in a non-volatile memory.

14. The method according to claim 13, wherein the memory cell addresses of the functionally inefficient memory cells are linked with the memory cell addresses of the redundancy memory.

15. A method for operating a memory module, the memory module comprising at least one memory buffer comprising a memory logic unit connected with at least one memory-side bus system and at least one host-side bus system; and at least one redundancy memory, wherein a comparison of at least one memory cell address of the memory logic unit with at least one further memory cell address can be performed, and a transmission of at least one bus signal can be switched between the memory-side bus system and the redundancy memory based on the comparison; and at least one semiconductor device connected therewith via the memory-side bus system, wherein
the memory cell addresses of the functionally inefficient memory cells are read out of the non-volatile memory and are written into the additional address register, and
memory cell addresses received in the memory logic unit at the host side are compared with the further memory cell addresses stored in particular in the additional address register, and
depending on the outcome of the comparison, at least one bus signal is either transmitted via the memory-side bus system or to the redundancy memory,
the further memory cell addresses stored in the redundancy memory correspond to defective memory cells, and
on concurrence between memory cell addresses received in the memory logic unit and memory cell addresses stored in the additional address register, a bus signal is transmitted to the redundancy memory.
